(19) United States
(12) Patent Application Publication
(10) Pub. No.: US 2021/0020630 A1
(43) Pub. Date: Jan. 21, 2021

(54) HIGH-VOLTAGE TOLERANT SEMICONDUCTOR ELEMENT

(71) Applicant: NEXCHIP SEMICONDUCTOR CO., LTD., Hefei (CN)

(72) Inventors: MASATOSHI TAYA, HYOGO (JP); NORIO NAKANO, KANAGAWA (JP); YASUHIRO KUMAGAI, TOKYO (JP)

(73) Assignee: NEXCHIP SEMICONDUCTOR CO., LTD., HEFEI (CN)

(21) Appl. No.: 16/901,366

(22) Filed: Jun. 15, 2020

(30) Foreign Application Priority Data
Apr. 15, 2019 (CN) 201910299871.0
Apr. 15, 2019 (JP) P2019-077044

(51) Int. Cl. H01L 27/088; H01L 21/8234

(52) U.S. Cl. CPC H01L 27/088; H01L 21/823437; H01L 21/823425

(57) ABSTRACT

The present disclosure provides a high-voltage tolerant semiconductor element preventing performance deterioration caused by impurity diffusion. The high-voltage tolerant semiconductor element includes a source portion (S), a well impurity region (PW) disposed around the source portion (S), and at least two gate portions (G) disposed at two sides of the source portion (S). An impurity concentration of the well impurity region is higher than an impurity concentration of a silicon substrate. A space between the two gate portions (G) is greater than a diffusion length (DD) of impurities.

### TECHNICAL FIELD

The present disclosure relates to a high-voltage tolerant semiconductor element.

### BACKGROUND

In an existing semiconductor element of an metal oxide semiconductor (MOS) structure, under the condition (multi-finger) of dividing a gate to ensure a width (trench width) of the gate or under the condition of sharing a source of different transistors with different purposes to reduce a layout area, a structure of sharing the source by two gates is laid out.

However, in a high-voltage tolerant MOS HVMOS element, under the condition that a well impurity region (a well region formed around the source and obtained by being implanted with impurities) is formed around the source sandwiched by the gates, impurities implanted into the well impurity region are diffused in an annealing process. Therefore, if the distance between the gates (a region into which the impurities are implanted for the well impurity region) is narrow, the implanted impurities are diffused in the annealing process, and the impurity concentration around the source is reduced. If the impurity concentration around the source is reduced, the threshold voltage may be reduced or the voltage tolerant performance may be reduced.

In the past, the space between gates in structures such as a multi-finger was designed in a space-saving manner by only considering a tolerance of a contact portion of the source, without considering the reduction of the impurity concentration of the well impurity region.

### SUMMARY

The present disclosure provides a high-voltage tolerant semiconductor element, which prevents performance deterioration caused by impurity diffusion.

In embodiments of the present disclosure, the high-voltage tolerant semiconductor element includes a source portion, a well impurity region disposed around the source portion, and two gate portions disposed at two sides of the source portion. An impurity concentration of the well impurity region is higher than an impurity concentration of a silicon substrate. A space between the gate portions is a first distance, and the first distance is in a range of 1.2 μm to 2.2 μm.

According to the above structure, in a semiconductor element with two gate portions sharing a source portion, the space between the gate portions is greater than a diffusion length (first distance) of impurities in an annealing process, the reduction of the impurity concentration in the well impurity region can be inhibited. Compared with a semiconductor element structure with an unshared source portion, the semiconductor element according to the present application can inhibit performance deterioration.

In the above high-voltage tolerant semiconductor element, when an implantation region of the impurities before the annealing process is overlapped with the gate portions, the space between the gate portions is a second distance. The second distance is shorter than the first distance.

Optionally, when the implantation region of the impurities before the annealing process is overlapped with the gate portions, an overlapping length (overlapping length of the implantation region of the impurities and the gate portions) can be shortened in the space region of the gate portions, and performance deterioration can be inhibited.

Optionally, the diffusion length may be a distance from a boundary position of the region implanted with the impurities before the annealing process to a position of the impurity concentration reduced to a specified value due to concentration diffusion in the annealing process.

Optionally, the distance from the boundary position of the region implanted with the impurities before the annealing process to the position of the impurity concentration reduced to the specified value due to concentration diffusion in the annealing process is the diffusion length, so that the diffusion length can be presumed based on annealing conditions.

Optionally, the diffusion length is set based on the annealing conditions in the annealing process.

Optionally, the annealing conditions include a treatment temperature and a treatment time in the annealing process.

Optionally, by using the treatment temperature and the treatment time in the annealing process as the annealing conditions, the diffusion length can be more precisely set.

Optionally, the annealing conditions may be set according to required voltage tolerant performance.

Optionally, by setting the annealing conditions according to the required voltage tolerant performance, the diffusion length can be more precisely set.

Optionally, the first distance has a value obtained by adding the diffusion length and a predetermined tolerance based on manufacturing errors together.

Optionally, the space between the gate portions is set considering the manufacturing errors.

Optionally, the tolerance based on the manufacturing errors can be properly set.

Optionally, the tolerance is 0.2 μm.

Optionally, the first distance as the space between the gate portions is properly set.

Optionally, the first distance is in a range of 1.2 μm to 2.2 μm.

Optionally, the first distance as the space between the gate portions can be set.

Optionally, the first distance is in a range of 1.3 μm to 2.0 μm.

Optionally, the second distance as the space between the gate portions can be properly set.

Optionally, the second distance is in a range of 0.8 μm to 2.0 μm.

According to the present disclosure, an effect of preventing performance deterioration caused by impurity diffusion can be achieved.

### BRIEF DESCRIPTION OF THE DRAWINGS

FIG. 1 is a cross-sectional view of a high-voltage tolerant semiconductor element according to a first embodiment of the present disclosure.

FIG. 2 is a top view of the high-voltage tolerant semiconductor element according to the first embodiment of the present disclosure.

FIG. 3 is a schematic diagram of circuit of a multi-finger type transistor according to an embodiment.

FIG. 4 is a schematic diagram of circuit when a transistor is singly disposed.

FIG. 5 is a cross-sectional view of a high-voltage tolerant semiconductor element according to a reference example.

FIG. 6 is a schematic diagram showing an N-drift implantation process of the high-voltage tolerant semiconductor element according to the first embodiment of the present disclosure.

FIG. 7 is a schematic diagram showing a P-well implantation process of the high-voltage tolerant semiconductor element according to the first embodiment of the present disclosure.

FIG. 8 is a schematic diagram showing an annealing process of the high-voltage tolerant semiconductor element according to the first embodiment of the present disclosure.

FIG. 9 is a diagram showing an STI-gate forming process of the high-voltage tolerant semiconductor element according to the first embodiment of the present disclosure.

FIG. 10 is a diagram showing a source/drain forming process of the high-voltage tolerant semiconductor element according to the first embodiment of the present disclosure.

FIG. 11 is a diagram showing an insulating film forming process of the high-voltage tolerant semiconductor element according to the first embodiment of the present disclosure.

FIG. 12 is a schematic diagram showing a structure of a gate.

FIG. 13 is a schematic diagram showing a peripheral structure of the gate of the high-voltage tolerant semiconductor element according to the first embodiment of the present disclosure.

FIG. 14 is a schematic diagram showing an Id-Vgs characteristic of the high-voltage tolerant semiconductor element according to the reference example.

FIG. 15 is a schematic diagram showing an Id-Vgs characteristic of the high-voltage tolerant semiconductor element according to the first embodiment of the present disclosure.

FIG. 16 is a cross-sectional view of a high-voltage tolerant semiconductor element according to a second embodiment of the present disclosure.

### DESCRIPTION OF REFERENCE NUMERALS

1 High-voltage tolerant semiconductor element
CT Contact portion
D Drain portion
DD Diffusion length
FD First distance
G Gate portion
GO Gate oxide film
GR Guard ring
I Implantation region
IF Insulating film
ND N-drift region
PW Well impurity region
PS Polycrystalline silicon layer
PR Photoresist layer pattern
S Source portion
SD Second distance
W Well portion

### DETAILED DESCRIPTION OF THE PREFERRED EMBODIMENTS

### Embodiment 1

The embodiment 1 of a high-voltage tolerant semiconductor element according to the present disclosure is illustrated with reference to the accompanying drawings hereafter.

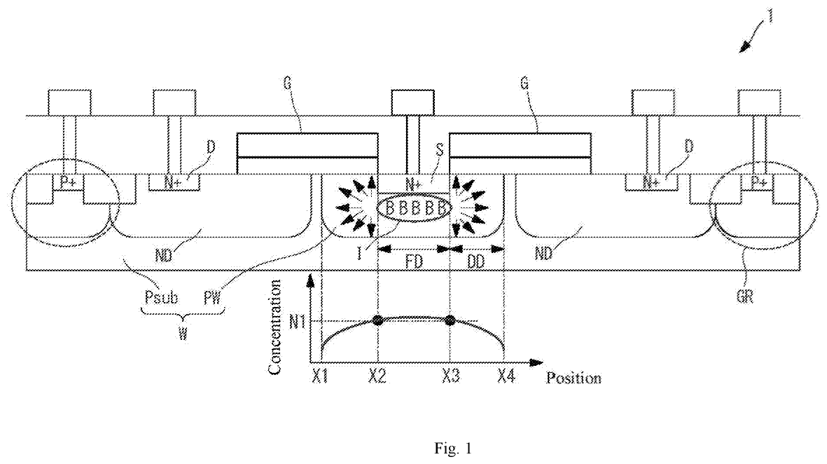

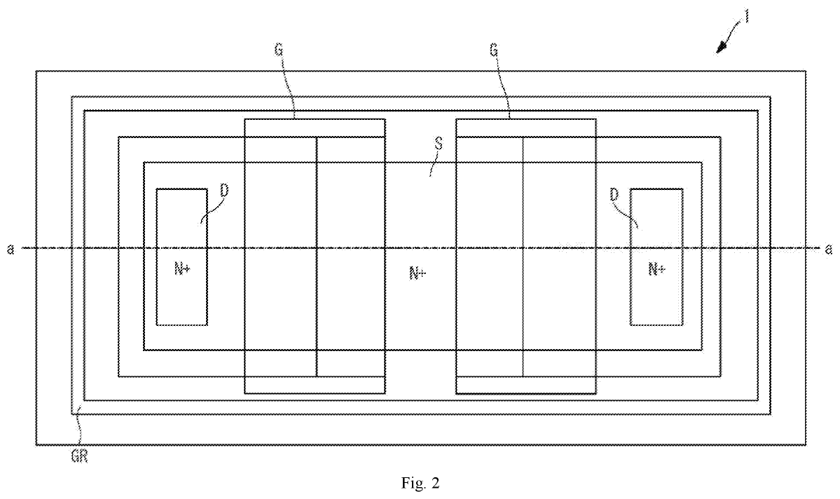

FIG. 1 is a cross-sectional view of a high-voltage tolerant semiconductor element 1 according to embodiment 1 of the present disclosure. FIG. 2 is a top view of the high-voltage tolerant semiconductor element 1 according to embodiment 1 of the present disclosure. The cross-sectional view in FIG. 1 is a cross-sectional view of an a-a plane in the top view in FIG. 2. As shown in FIG. 1 and FIG. 2, the high-voltage tolerant semiconductor element 1 according to the present embodiment is a semiconductor element of an MOS structure. The semiconductor element includes a source portion S, a gate portion G, a drain portion D, and a well portion W. The high-voltage tolerant semiconductor element 1 according to the present embodiment is applicable even a gate of one transistor is divided (multi-finger type) or the source portion S of different transistors with different purposes is shared.

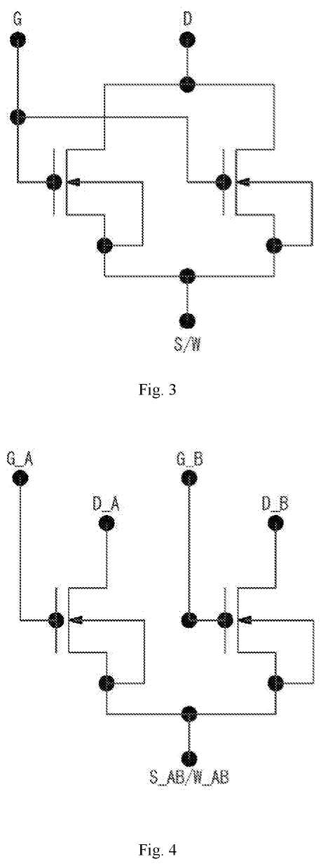

A multi-finger transistor is an element dividing the gate portion G into a plurality of gates for laying out. A region between the two adjacent gate portions G is used as the source portion S or the drain portion D, the terminals shares gate portions G to reduce the area of the transistor. Under the condition of dividing the gate portion G into three gate portions (3 fingers) or more, the source portion S is necessarily shared. Under the condition of dividing the gate portion G into two gate portions (2 fingers), the drain portions D is shared, as shown in FIG. 3. According to FIG. 3, the source portion S, the gate portions G, the well portion W, and the drain portions D are respectively connected with each other. Under the condition that an element of the MOS structure is laid out on the silicon substrate, the area of the transistor can be reduced by sharing the terminal of the source portion S. In addition, according to FIG. 3, the well portion W and the source portion S are at the same potential, but different potentials can also be provided.

The source portions S of the transistors with different purposes are shared, for example, according to a circuit structure shown in FIG. 4. That is, in each transistor, gate portions G_A and G_B and drain portions D_A and D_B are used (controlled) for various purposes, and a source portion S_AB and a well portion W_AB are shared. Even under this condition, each transistor can be laid out by sharing the source portion S_AB on the silicon substrate, so that the area of the transistor can be reduced. The well portion W_AB and the source portion S_AB shown in FIG. 4 are at the same potential, but different potentials can also be provided.

The high-voltage tolerant semiconductor element 1 according to the present embodiment also becomes the same structure even the multi-fingers share the source portion S or the source portion S of the transistors with different purposes is shared. That is, according to a wiring state of the gate portions G and the drain portions D in the high-voltage tolerant semiconductor element 1 shown in FIG. 1, the semiconductor element 1 is applicable to any purpose. In the present embodiment, an example of a multi-finger (2-finger) type is illustrated, in which the gate portion G of one transistor is divided into two gate portions, but it is also applicable to a condition that the source portion S of the transistors for different purposes is shared.

As shown in FIG. 1 and FIG. 2, one source portion S is disposed in the high-voltage tolerant semiconductor element 1. The source portion S is shared by a plurality of gates G. The gate portions G are disposed at two sides of the shared source portion S, the current conduction state may change according to a control state of the gate portions G.

A well impurity region PW is disposed around the source portion S. The well impurity region PW and a continuous silicon substrate Psub region are together used as a well portion W. An impurity concentration of the well impurity region PW is higher than that of the silicon substrate. In FIG. 1, the well impurity region PW is formed by implanting impurities into an implantation region I and the implanted impurities diffusing in a specified region in the annealing process. The implantation region I is configured to be implanted with the impurities to form the well impurity region PW. For the source portion S, N-type impurities (such as arsenic) are doped to form an expected impurity concentration. At the moment, the gate portions G can be used as masks to form an N+ source region between the gate portions G. The region between the gate portions G is a plane region equal to the implantation region I. The well impurity region PW is formed in a specified region around the source portion S by performing diffusion relative to the implantation region I of the impurities in the annealing process. The source portion S is activated through short-time heat treatment, and is formed in a region on the surface of the silicon substrate and equal to the implantation region I (i.e., a region between the gate portions G).

In the well impurity region PW, in order to obtain a proper threshold voltage (Vth), an impurity concentration in a region right below the gate portions G may be regulated. That is, the impurities between X1 and X2 and between X3 and X4 in FIG. 1 will have the expected concentration after annealing. N1 represents the impurity concentration at X2 and X3 after annealing.

The gate portions G are disposed at two opposite sides of the source portion S. Specifically, the gate portions G are adjacently disposed at two ends of the shared source portion S (N+ source region). That is, in the present embodiment, the space between the gate portions G is the source portion S (N+ source region). The source portion S is formed on the surface of the silicon substrate and in a region equal to the implantation region I, the space between the gate portions G is equal to the space of the embodiment region I. That is, as shown in FIG. 1, in the high-voltage tolerant semiconductor element 1 according to the present embodiment, the space between the gate portions G, the source portion S (N+ source region) and the implantation region I are equal in a direction parallel to the silicon substrate.

The space between the gate portions G is set to be a first distance FD. The first distance FD is greater than a diffusion length DD of the impurities. In the present embodiment, the first distance FD of the space between the gate portions G is illustrated under the condition that the diffusion length DD of the impurities is set in FIG. 1, the first distance FD is greater than the diffusion length DD. It is worth noting that a space (or a first distance region) between the two gate portions G refers to a region of the source portion S, and is a non-implantation region I.

The diffusion length DD is a distance from a boundary position of the region implanted with the impurities before the annealing process (a boundary position of the implantation region I) to a position of the impurity concentration reduced to a specified value due to the diffusion in the annealing process. The specified value of the concentration is, for example, preset to be a proportion relative to the concentration of the implanted impurities.

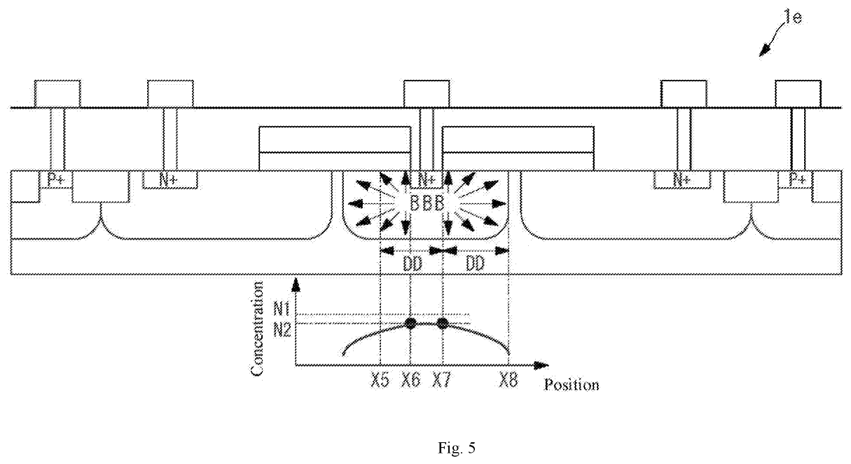

In the annealing process, the impurities implanted into the well impurity region PW (implantation region I) are subjected to heat treatment at a high temperature, for example, 1100° C., for several hours. During the heat treatment, the implanted impurities diffuse in the silicon substrate. FIG. 5 shows a diagram of impurity diffusion in a high-voltage tolerant semiconductor element 1e according to a reference example. In the reference example, the space between the gate portions G is less than the diffusion length DD of the impurities. That is, a region (implantation region) between X6 and X7 is less than the diffusion length DD. In the reference example, the impurities implanted into the implantation region diffuse to reach a distance of the diffusion length DD. In FIG. 5, the impurities implanted into the X7 position diffuse to X5 and X8 positions due to the annealing process. Likewise, the impurities implanted between X6 and X7 respectively diffuse to a distance of the diffusion length DD to form the impurity concentration of a region between X7 and X8 right below the gate portions G. As shown in the reference example, the space between the gate portions G is less than the diffusion length DD, the impurities are not implanted between X5 and X6. Therefore, compared with the space between the gate portions G is greater than the diffusion length DD, the impurities reaching the region between X7 and X8 are reduced. N2 represents the impurity concentration at the X7 position, which is reduced compared with an expected concentration N1, and so is the impurity concentration at N2 at X6. Therefore, the expected impurity concentration cannot be met, and the threshold voltage (Vth) or voltage tolerant performance may be reduced.

The space between the gate portions G according to the present embodiment is set to be the first distance FD. The first distance FD is set to be greater than the diffusion length DD. In other words, the impurities are implanted into the implantation region I with a width of the first distance FD. The gate portions G are disposed at two ends (separated by the first distance FD) of the implantation region I. By setting the space (the implantation region I) between the gate portions G to be the first distance FD greater than the diffusion length DD, even if concentration diffusion is generated in the annealing process, the reduction of the impurity concentration right below the gate portions G can be inhibited, and performance reduction can be inhibited. In FIG. 1, the impurities are implanted into the implantation region I between X2 and X3, and diffusion is performed in the annealing process. That is, the well impurity region PW is formed through the diffusion to the X1 and X4 positions. However, since the space between the gate portions G is greater than the diffusion length DD, the reduction of the impurity concentration of the well impurity region PW near the source portion S is inhibited. In FIG. 1, the impurity concentration reaching the X2 and X3 positions is not reduced, and N1 as the expected impurity concentration is obtained.

The diffusion length DD may be set based on annealing conditions in the annealing process. The annealing conditions include the annealing temperature and the anneal time. That is, the diffusion length DD can be presumed as long as the treatment temperature and the treatment time in the annealing process are known, and the element can be designed according to the presumed diffusion length DD.

The annealing conditions are generally set according to required voltage tolerant performance. The required voltage tolerant performance is, for example, the voltage tolerance. The higher the required voltage tolerant performance is, the greater the diffusion length DD is. Therefore, by correspondingly setting the annealing temperature and the annealing temperature according to the required voltage tolerant performance, the diffusion length DD can be more precisely obtained.

The first distance FD as the space between the gate portions G is set to be greater than the diffusion length DD corresponding to the voltage tolerant specification, so that the first distance FD is not influenced by a process for manufacturing the element. Therefore, the first distance as the specific space between the gate portions G is, for example, set to be in a range of 1.2 μm to 2.2 μm. The space between the gate portions G may be further set to be in a range of 1.3 μm to 2.0 μm.

The drain portions D are respectively disposed corresponding to each gate portion G. In the drain portions D, an N+ drain region can be formed by implanting the N-type impurities (such as arsenic). The drain portions D are disposed in a manner of being separated by a distance from the gate portions G. N-drift regions ND are formed on the silicon substrate surface between the gate portions G and the drain portions D. The N-drift regions ND are formed between the gate portions G and the drain portions D, a transverse electric field of the drain portions D can be relieved to ensure the high-voltage tolerant performance. In the present embodiment, a multi-finger (2-finger) type structure of sharing the source portion S is used, so that the drain portions D in FIG. 1 and FIG. 2 are disposed in a bilaterally symmetrical way. Structures on the peripheries of the gate portions G and the drain portions D are not limited to the structures in FIG. 1. For example, shallow trench isolation (STI) may be formed between the gate portions G and the drain portions D. When the gate portion G is divided into three or more fingers, the drain portion D between the gate portions G is also shared.

Additionally, as shown in FIG. 1 and FIG. 2, the high-voltage tolerant semiconductor element 1 may be surrounded by a guard ring GR. The guard ring GR can improve the isolation characteristics by meeting the voltage tolerant specification between the guard ring GR and an adjacent element. The guard ring GR can function as an electrode structure relative to the well portion W of the high-voltage tolerant semiconductor element 1.

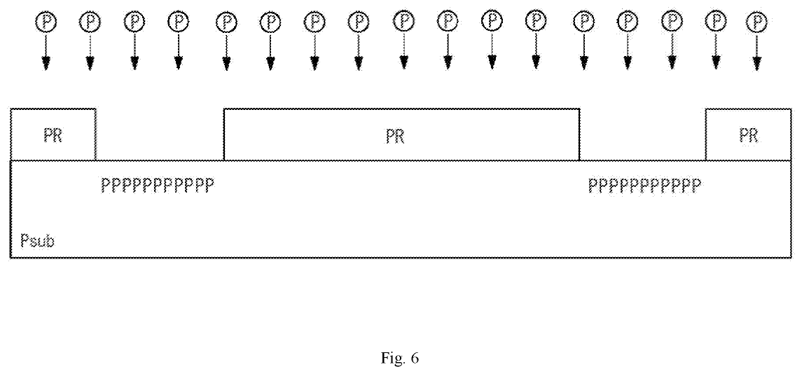

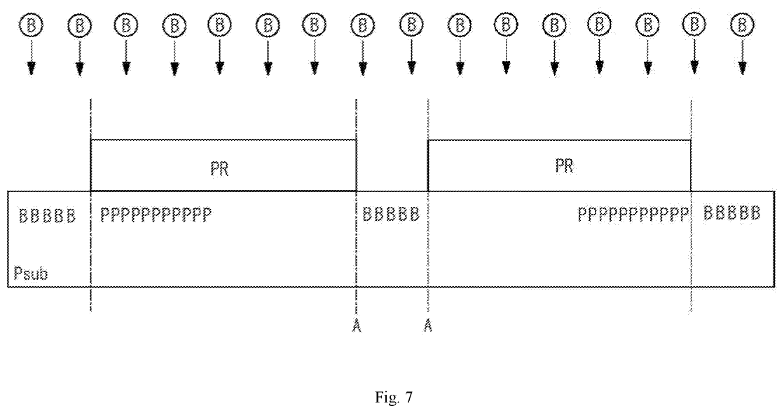

Then, referring to FIGS. 6 to 11, an example of a method (process flow) for manufacturing of the high-voltage tolerant semiconductor element 1 according to the present embodiment is illustrated.

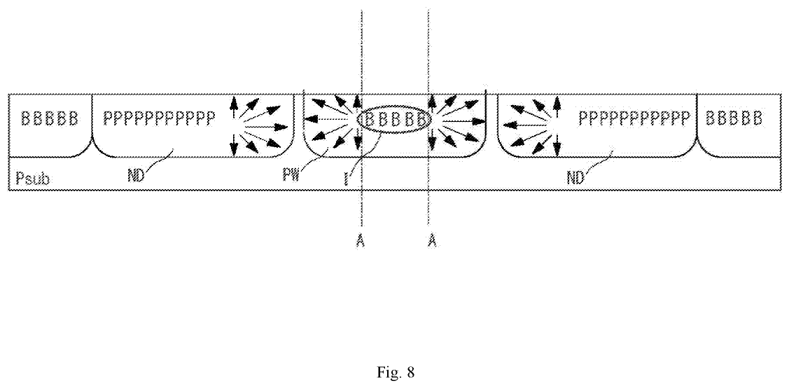

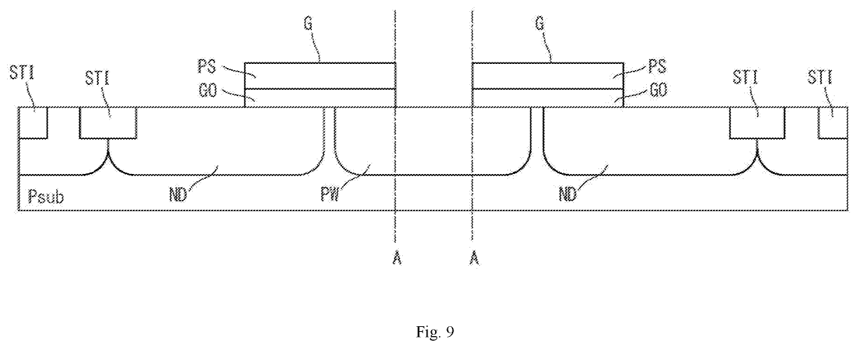

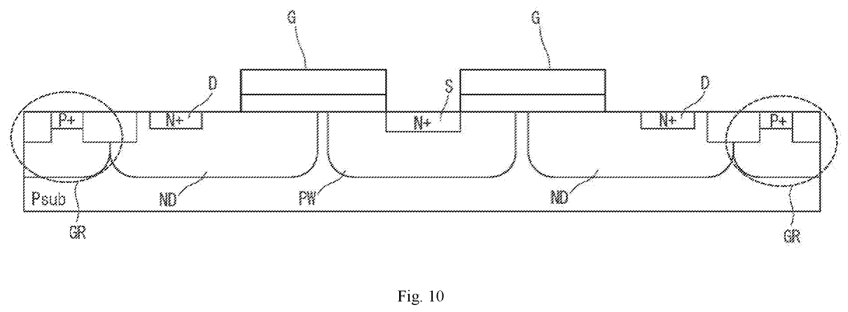

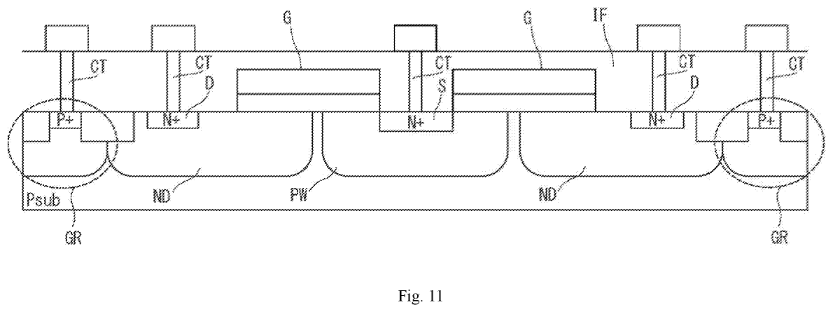

FIGS. 6 to 11 are schematic diagrams showing manufacturing processes of the high-voltage tolerant semiconductor element 1. FIG. 6 is a schematic diagram showing an N-drift implantation process. FIG. 7 is a schematic diagram showing a P-well implantation process. FIG. 8 is a schematic diagram showing an annealing process. FIG. 9 is a schematic diagram showing an STI-gate forming process. FIG. 10 is a schematic diagram showing a source/drain forming process. FIG. 11 is a schematic diagram showing a forming process of an insulating film and the like. In the present embodiment, the forming of the HVNMOS (P type substrate Psub) is illustrated, but it is also applicable to the forming of the HVPMOS.

In the N-drift implantation process in FIG. 6, N type impurities (such as phosphorus) are implanted into a region for forming an N-drift region ND aiming at the drain portions D on the silicon substrate. Photoresist layer patterns PR may be formed on a region beyond the region implanted with the impurities for forming the N-drift region ND, so as to avoid the impurity implantation.

In the P-well implantation process in FIG. 7, P-type impurities (such as boron) are implanted in a region (implantation region I) for forming the well impurity region PW aiming at the source portion S. In the embodiment shown in FIG. 7, the P-type impurities are also implanted into a region for forming the guard ring GR. The photoetching and implantation processes can be reduced by performing the implantation process simultaneously.

In the P-well implantation process, photoresist layer patterns PR are formed on the region for forming the gate portions G and the region implanted with the N-type impurities. The P-type impurities are implanted into other regions (the region for forming the source portion S). That is, end portions A of the photoresist layer patterns PR become the end portions of the gate portions G. Therefore, the P-type impurities can be implanted into the implantation region I.

In the annealing process (firing process) in FIG. 8, in order to activate the impurities implanted into crystal structures of the silicon substrate, high-temperature heat treatment is performed. The annealing process is heat treatment for a specified time at a specified temperature. Specifically, for example, heat treatment may be performed for several hours at 1100° C.

In the annealing process, the implanted impurities will diffuse. As shown in FIG. 8, the impurities implanted into the implantation region I diffuse to form the well impurity region PW which is wider than the implantation region I. Through diffusion, the impurity concentration in the well impurity region PW will generate a gradient in a direction parallel to the silicon substrate. However, since the distance of the implantation region I is set to be the first distance FD (greater than the distance of the diffusion length DD), the reduction of the impurity concentration in the well impurity region PW near the source portion S can be inhibited to ensure the sufficient concentration. Therefore, performance reduction caused by impurity concentration reducing in the well impurity region PW can be inhibited.

In the annealing process, the N-type impurities will also diffuse to form the N-drift region ND.

The impurity diffusion in the annealing process has a correlational relationship with the annealing conditions (treatment temperature and treatment time) in the annealing process. Therefore, in order to realize the expected performance, the diffusion length DD may be designed in advance, and the annealing conditions are determined to obtain the designed diffusion length DD.

In the STI-gate forming process in FIG. 9, STI and the gate portions G are formed on the surface of the silicon substrate. The STI is a structure for element isolation. Trenches are formed in predetermined positions, and silicon oxide films are buried into the trenches. The STI is formed by using isolators, so that each component formed on the surface of the silicon substrate are electric isolated from each other.

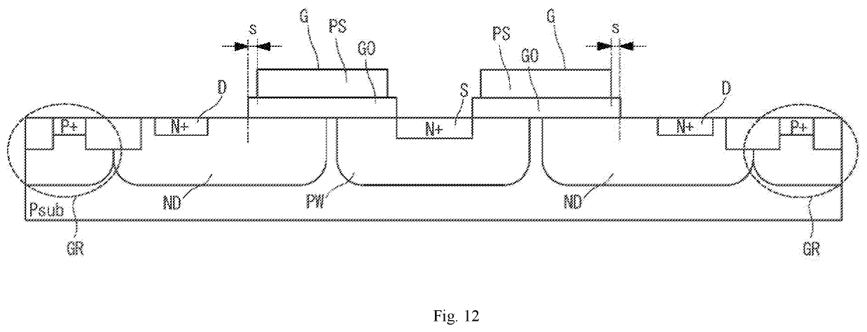

The gate portions G are formed at specified positions on the surface of the silicon substrate. Gate oxide film GO used as insulator is formed on the silicon substrate. Polycrystalline silicon layer PS is formed on the gate oxide films GO. In the gate portions G shown in FIG. 12, the width of the polycrystalline silicon layer PS may be less than the width of the gate oxide film GO. In FIG. 12, the width of the polycrystalline silicon layer PS is about 2 widths s less than that of the gate oxide films GO. Therefore, the possibility of a short circuit between the surface of the silicon substrate and the polycrystalline silicon layer PS can be reduced.

In the source/drain forming process in FIG. 10, the source portion S and the drain portions D are formed at predetermined positions. The source portion S is formed by implanting the N-type impurities (such as arsenic) into the region between the gate portions G. In the present embodiment, a region between the end portions of the two gate portions G is used as the implantation region I of the well impurity region PW, therefore the source portion S may be formed in a region the same as the implantation region I on the silicon substrate. That is, the space between the gate portions G is the width of the implantation region I, and is the width of the source portion S.

The drain portions D are formed in the N-drift region ND, and have a predetermined distance from the gate portions G. The drain portions D are formed by implanting the N-type impurities (such as arsenic) into a predetermined region. In order to form the guard ring GR, the P-type impurities (such as boron) may be implanted into the specified region.

In the forming process of the insulating film shown in FIG. 11, insulating films IF and contact portions CT are formed on the silicon substrate. In the forming process of the insulating film, a thick silicon oxide film is formed on the silicon substrate formed with the gate portions G by methods such as a CVD to form the insulating films IF. Then, the contact portions CT configured to perform wiring connection on each terminal of the element and other elements are formed. The contact portions CT are formed by forming contact holes in the insulating films IF by etching and embedding tungsten in the contact holes. Therefore, CT (contact portion) layers are formed in the forming process of the insulating film. Metal wirings (metal layers) are laid on the surfaces of the CT layers.

The processes shown in FIGS. 6 to 11 are only one example of a flow process for manufacturing the high-voltage tolerant semiconductor element 1. The processes or the sequence are not limited to the above conditions, as long as the high-voltage tolerant semiconductor element 1 of the structure shown in FIG. 1 can be manufactured.

In the present embodiment, on one hand, the implantation region I of the impurities before the annealing process may be not overlapped with the gate portion G That is, under the condition that the implantation region I is not overlapped with the gate portion G, the space between the gate portions G is greater than the distance of the diffusion length DD (the first distance FD), the implantation region I can be greater than the distance of the diffusion length DD. Even if concentration diffusion is generated in the annealing process, the reduction of the impurity concentration in the well impurity region PW right below the gate portions G can be inhibited.

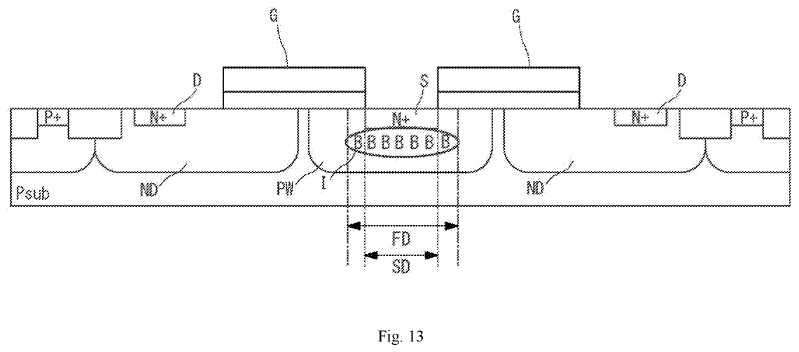

On the other hand, as shown in FIG. 13, the implantation region I of the impurities before the annealing process may be overlapped with the gate portion G. Under the condition that the implantation region I is overlapped with the gate portions G, even if the implantation region I is greater than the distance of the diffusion length DD, space between the gate portions G can shorten the overlapping portion. Therefore, under the condition that the implantation region I of the impurities before the annealing process is overlapped with the gate portions G, the space between the gate portions G may also be a second distance SD. The second distance SD is shorter than the first distance FD. The second distance SD is, for example, in a range of 0.8 μm to 2.0 μm.

Based on the above, in the high-voltage tolerant semiconductor element according to the present embodiment, the source portion S are shared by the gate portions G, the space between the gate portions G is set to be the first distance FD, therefore the reduction of the impurity concentration in the well impurity region PW can be inhibited. The first distance FD is greater than the diffusion length DD of the impurities in the annealing process. Therefore, compared with a semiconductor element with an unshared source portion S, the high-voltage tolerant semiconductor element can inhibit performance deterioration.

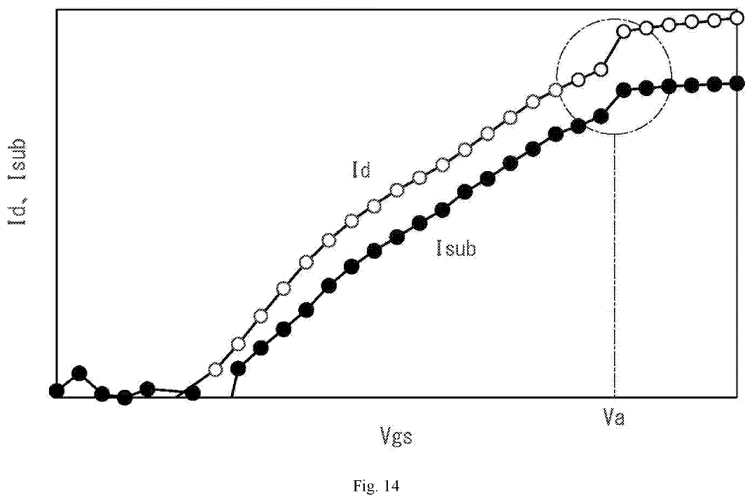

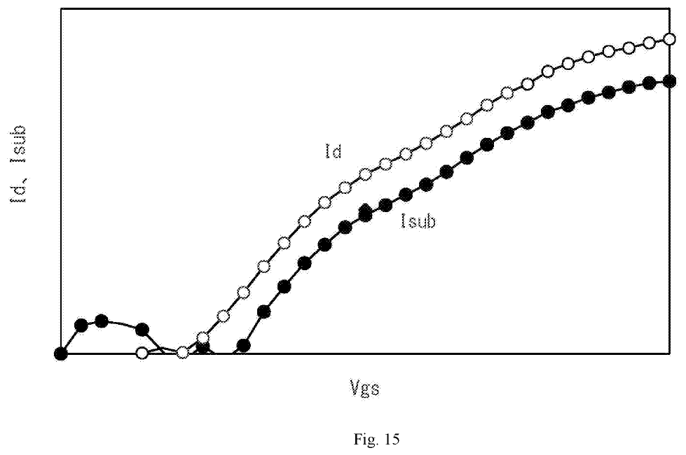

FIG. 14 shows an Id-Vgs characteristic (a characteristic representing a relationship of a drain current and a voltage between the gate and the source) under the condition of applying the maximum-specification voltage such as 35 V to the drain portions D of the high-voltage tolerant semiconductor element 1 according to the reference example shown in FIG. 5. FIG. 14 further shows an Isub-Vgs characteristic (a characteristic representing a relationship of a substrate current and the voltage between the gate and the source). In the reference example, the space between the gate portions G is less than the diffusion length DD of the impurities, for example, is 0.8 μm. FIG. 15 shows an Id-Vgs characteristic under the condition of applying the maximum-specification voltage such as 35 V to the drain portions D of the high-voltage tolerant semiconductor element 1 according to the present embodiment. FIG. 15 further shows an Isub-Vgs characteristic (a characteristic representing a relationship of the substrate current and the voltage between the gate and the source).

In the reference example, the space between the gate portions G is not large enough. In other words, the width of the implantation region I is less than the diffusion length DD, so that the impurity concentration in the well impurity region PW of the source portion S is reduced. Therefore, as shown in FIG. 14, breakdown occurs at Va (for example, 2 V). This is because the concentration of the impurities in the well impurity region PW reduces and the resistance value increases. Since large Isub (substrate current) flows through, the higher the resistance value is, the easier the potential drift of the well portion W is, and the breakdown based on a snapback phenomenon is caused.

In the present embodiment, the space between the gate portions G is designed according to the diffusion length DD. Therefore, as shown in FIG. 15, the breakdown shown in FIG. 14 can be avoided. That is, the impurity concentration reducing caused by diffusion in the drain region is inhibited, so that performance deterioration can be prevented.

### Embodiment 2

A high-voltage tolerant semiconductor element according to embodiment 2 of the present disclosure is illustrated.

In the present embodiment, manufacturing errors is considered in designing the space between gate portions G. The differences between the high-voltage tolerant semiconductor element according to the present embodiment and the first embodiment are illustrated.

As shown in FIG. 1, the semiconductor element may be manufactured by a photoetching technology. The dimension deviation, which is tiny, may cause the manufacturing errors. If the manufacturing errors are generated in the semiconductor element shown in FIG. 1, the space between the gate portions G (the width of the implantation region I) may be less than the diffusion length DD in the annealing process. If the space between the gate portions G (the width of the implantation region I) is less than the diffusion length DD in the annealing process, performance deterioration as illustrated in the reference example may be caused. Therefore, in the present embodiment, the manufacturing errors also need to be considered.

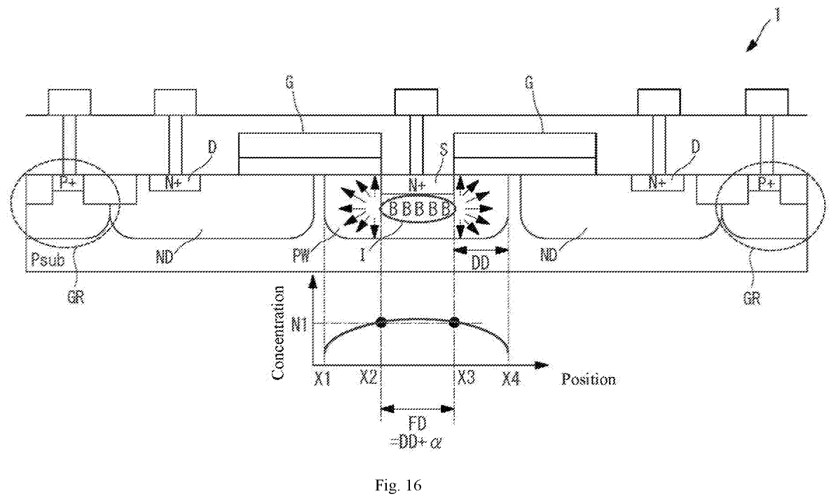

Specifically, the first distance FD is set to be a value obtained by adding the diffusion length DD and a specified tolerance based on the manufacturing errors together. The first distance FD as the space between the gate portions G is greater than the diffusion length DD. Therefore, performance deterioration caused by diffusion can be inhibited. In order that the first distance FD cannot be less than the diffusion length DD due to the manufacturing errors, the first distance FD is set to be the value obtained by adding the diffusion length DD and the tolerance based on the manufacturing errors together. FIG. 16 is a schematic diagram representing a cross-sectional view of the high-voltage tolerant semiconductor element 1 according to the present embodiment. As shown in FIG. 16, the space between the gate portions G of the high-voltage tolerant semiconductor element 1 is the distance (first distance FD) obtained by adding the diffusion length DD and the specified tolerance a together.

The specified tolerance is set based on the manufacturing errors of the semiconductor element. Specifically, the specified tolerance is set to be 0.2 μm.

As illustrated above, in the high-voltage tolerant semiconductor element according to the present embodiment, the space between the gate portions G is set further considering the manufacturing errors, and the performance deterioration can be more reliably prevented.

The present disclosure is not limited to the foregoing embodiments, and various modifications may be made without departing from the gist of the present disclosure. In addition, various embodiments may be combined.

What is claimed is:

1. A high-voltage tolerant semiconductor element, comprising:
a source portion;
a well impurity region, disposed around the source portion, wherein an impurity concentration of the well impurity region is higher than an impurity concentration of a silicon substrate; and
at least two gate portions, disposed at two sides of the source portion, wherein a space between the gate portions is greater than a diffusion length of impurities, and is in a range of 1.2 μm to 2.2 μm.

2. The high-voltage tolerant semiconductor element as in claim 1, wherein
the space between the gate portions is in a range of 1.3 μm to 2.0 μm.

3. The high-voltage tolerant semiconductor element as in claim 1, wherein
when an implantation region of the impurities is overlapped with the gate portions, the space between the gate portions is in a range of 0.8 μm to 2.0 μm.

4. A method for manufacturing a high-voltage tolerant semiconductor element, comprising:
an implantation step: implanting impurities into an implantation region on a surface of a silicon substrate;
an annealing step: performing heat treatment on the silicon substrate;
a gate forming step: forming two gate portions separated by a first distance on the silicon substrate with respect to a center point of the implantation region on the surface of the silicon substrate, wherein the first distance is in a range of 1.2 μm to 2.2 μm; and
a source forming step: forming a source portion between the gate portions.

5. The method for manufacturing a high-voltage tolerant semiconductor element as in claim 4, wherein
the first distance is in a range of 1.3 μm to 2.0 μm.

6. The method for manufacturing a high-voltage tolerant semiconductor element as in claim 4, wherein
when the implantation region of the impurities is overlapped with the gate portions, the space between the gate portions is a second distance, and the second distance is shorter than the first distance.

7. The method for manufacturing a high-voltage tolerant semiconductor element as in claim 6, wherein
the second distance is in a range of 0.8 μm to 2.0 μm.
